(19) United States
(12) Patent Application Publication
(10) Pub. No.: US 2002/0140064 A1
(43) Pub. Date: Oct. 3, 2002

(54) Semiconductor chip package and lead frame structure thereof

(75) Inventors: Yu-Chai Wu, Sanmin chiu Kaohsiung (TW); Shih-Wen Chou, Tainan (TW)

Correspondence Address: Benjamin J. Hauptman, LOWE HAUPTMAN GILMAN & BERNER, LLP, 1700 Diagonal Road, Suite 310, Alexandria, VA, 22314, US

(73) Assignee: ADVANCED SEMICONDUCTOR ENGINEERING INC.

(21) Appl. No.: 09/819,822

(22) Filed: Mar. 29, 2001

(51) Int. Cl. H01L 23/495

(52) U.S. Cl. 257/670; 257/676; 257/690; 257/701

(57) ABSTRACT

A semiconductor chip package comprises a lead frame having a plurality of leads defining a center area, and a die pad located on the center area of the leads and having at least one downward protuberance on the edge of the die pad; a semiconductor chip attached on the die pad and having a plurality of bonding pads located on the active surface thereof; a plurality of bonding wires connecting the leads and the bonding pads of the semiconductor chip; and a package body encapsulating the lead frame, the semiconductor chip and the bonding wires, wherein the at least one protuberance of the die pad of the lead frame is exposed outside the package body.

### BACKGROUND OF THE INVENTION

1. Field of the Invention

This invention relates to a semiconductor chip package, and more specifically to a lead frame of a semiconductor chip package.

2. Description of the Related Art

FIG. 1 depicts a conventional semiconductor chip package which comprises a lead frame for bearing a chip 100. The lead frame includes a plurality of leads each having an outer lead portion 106 and an inner lead portion (not indicated in the FIG. 1a). The chip 100 is attached to a die pad 111 through silver epoxy 114, and the die pad 111 is connected to the lead frame by a plurality of tie bars 119. The outer lead portions 106 of the lead frame are used for connecting electrically to an external circuit. The chip 100 has a plurality of bonding pads 117 connected electrically to the leads of the lead frame by a plurality of bonding wires 115. The chip 100, the die pad 111, the inner lead portions of the lead frame and the plurality of bonding wires 115 are encapsulated with a package body 116. The package body 116 is made of an isolated material, such as epoxy. Besides, as shown in FIG. 1, the die pad 111 is downset so the die pad 111 is below the inner leads of the lead frame. However, in the semiconductor packaging process, the die pad 111 and the bonding wires 115 are usually not positioned very well with each other as shown in FIG. 1. When the die pad 111 may be downset not enough, or the loop height of the bonding wires 115 may be too high, the apex of the bonding wires 115 will be exposed outside of the package body 116 (as shown in FIG. 2a). Obviously, the exposed bonding wires 115 should cause problems in electrical connection and has negative effect on the performance of the chip package. On the other hand, the die pad 111 may be downset too much such that the die pad 111 is exposed outside of the package body 116 (as shown in FIG. 2b). In this case, the package body 116 fails to isolate and prevent the moisture from infiltrating through the interface between the exposed die pad 111 and the package body 116. When the packaged chip is soldered onto a printed circuit board during the solder reflow (e.g. IR reflow by infrared irradiation), the infrared irradiation would convert the moisture to water vapor, which suddenly expands causing so-called vapor explosion, resulting in the cracks of the package body and lowering the quality of the chip package.

Alternatively, the drag force on the die pad 111 and the chip 100 or the insufficient strength of the tie bars 119 in the molding process of the semiconductor chip package will cause the shift of the die pad 111 and the chip 100 thereon. In the extreme case, either the bonding wires 115 would be exposed outside of the package body 116 or the die pad 111 would be exposed outside of the package body 116, or both will happen simultaneously (as shown in FIG. 2c).

U.S. Pat. No. 5,623,123, entitled “Semiconductor Device Package With Small Die Pad And Method of Making Same” issued on Apr. 22, 1997 to Umahara, discloses a lead frame with a smaller die pad, but the problem of die pad positioning in the packaging process of the chip remains still unsolved.

Therefore, a need exists for a semiconductor package with a lead frame of which the downset lead frame can be positioned more accurately so as to assure the quality of the semiconductor chip package.

### SUMMARY OF THE INVENTION

It is the primary object of the present invention to provide a semiconductor chip package and the lead frame structure thereof so as to increase the stability and the quality of the semiconductor chip package.

It is the secondary object of the present invention to provide a lead frame structure which can be positioned accurately in the packaging process to prevent the bonding wires from being exposed outside the package body.

It is another object of the present invention to provide a lead frame structure which can be positioned accurately in the packaging process to prevent the die pad from being exposed outside the package body.

In order to achieve the purposes mentioned hereinabove, the lead frame of the present invention mainly comprises a plurality of leads each having an inner portion defining a center area, a die pad located in the center area of the plurality of leads, a plurality of tie bars connecting the die pad to lead frame. The lead frame of the present invention is characteristized in that the die pad downsets below the inner portion of the plurality of leads and is provided with a plurality of downward protuberances.

According to the present invention, the semiconductor chip package comprises:

a lead frame having an upper surface and a lower surface, a plurality of leads each having an inner portion defining a center area, and a die pad located in the center area of the plurality of leads and connected to the lead frame by a plurality of tie bars, wherein the lower suface of the die pad is provided with a plurality of downward protuberances for positioning the die pad;

a semiconductor chip attached on the die pad and having a plurality of bonding pads located on the active surface thereof;

a plurality of bonding wires connecting the inner portions of the plurality of leads and the plurality of bonding pads of the semiconductor chip; and

a package body encapsulating the lead frame, the semiconductor chip and the plurality of bonding wires, wherein the protuberances of the die pad of the lead frame is exposed outside the package body.

Accoring to the present invention, the protuberances of the die pad are able to position the lead frame and the semiconductor chip on the lead frame. Therefore, the semiconductor package formed by the lead frame of the present invention can desirably position the chip, the bonding wires and the lead frame in place so as to assure the quality of the semiconductor chip package.

### BRIEF DESCRIPTION OF THE DRAWINGS

Other objects, advantages, and novel features of the invention will become more apparent from the following detailed description when taken in conjunction with the accompanying drawings.

FIG. 1 is a sectional schematic view of a conventional semiconductor chip package.

FIG. 2a is a sectional schematic view of a conventional semiconductor chip package showing the bonding wires exposed outside the package body.

FIG. 2b is a sectional schematic view of a conventional semiconductor chip package showing the die pad exposed outside the package body.

FIG. 2c is a sectional schematic view of a conventional semiconductor chip package showing the shift of the die pad and the chip thereon with the bonding wires and the die pad exposed outside the package body.

FIG. 3 is a partially top plan view of a lead frame structure according to an embodiment of the present invention.

FIG. 4 is a sectional schematic view of a semiconductor chip package according to the embodiment of the present invention.

FIG. 5 is a partially top plan view of a lead frame structure according to another embodiment of the present invention.

FIG. 6 is a sectional schematic view of a semiconductor chip package according to the embodiment of the present invention as shown in FIG. 5.

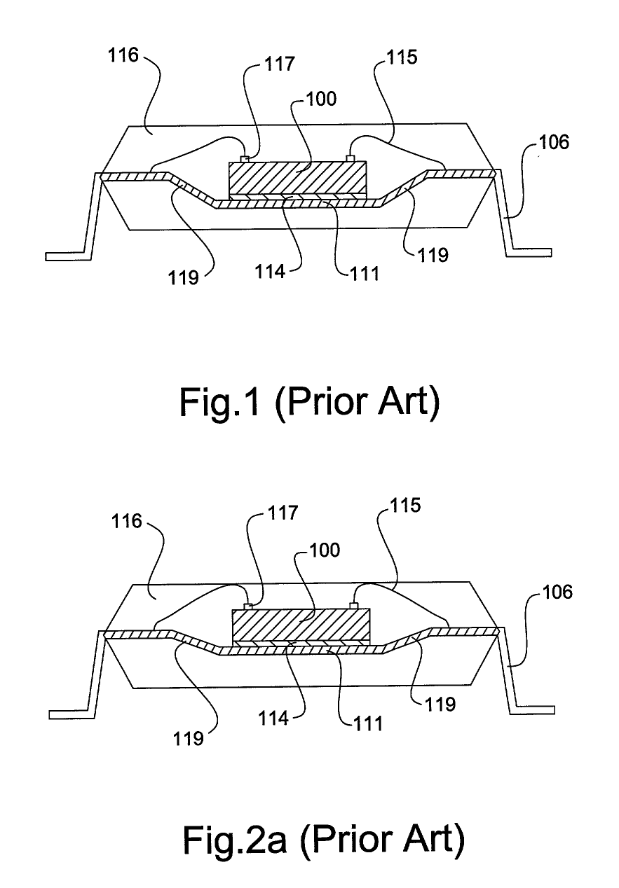

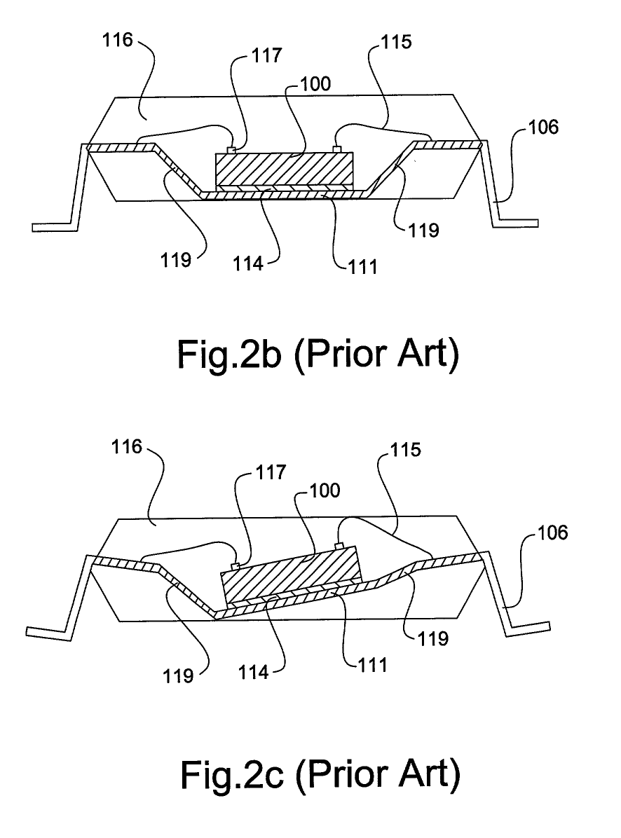

### DETAILED DESCRIPTION OF THE PREFERRED EMBODIMENT

The present invention relates to a lead frame structure which is used for positioning the chip, the bounding wires and the die pad of the semiconductor chip package in place so as to avoid the vapor explosion and cracks of the semiconductor chip package and lowering electrical performance of the semiconductor chip package Now preferable embodiments according to the present invention will be described in detail while taken in conjunction with the accompanying drawings. In the accompanying drawings, like reference numbers represent corresponding parts throughout.

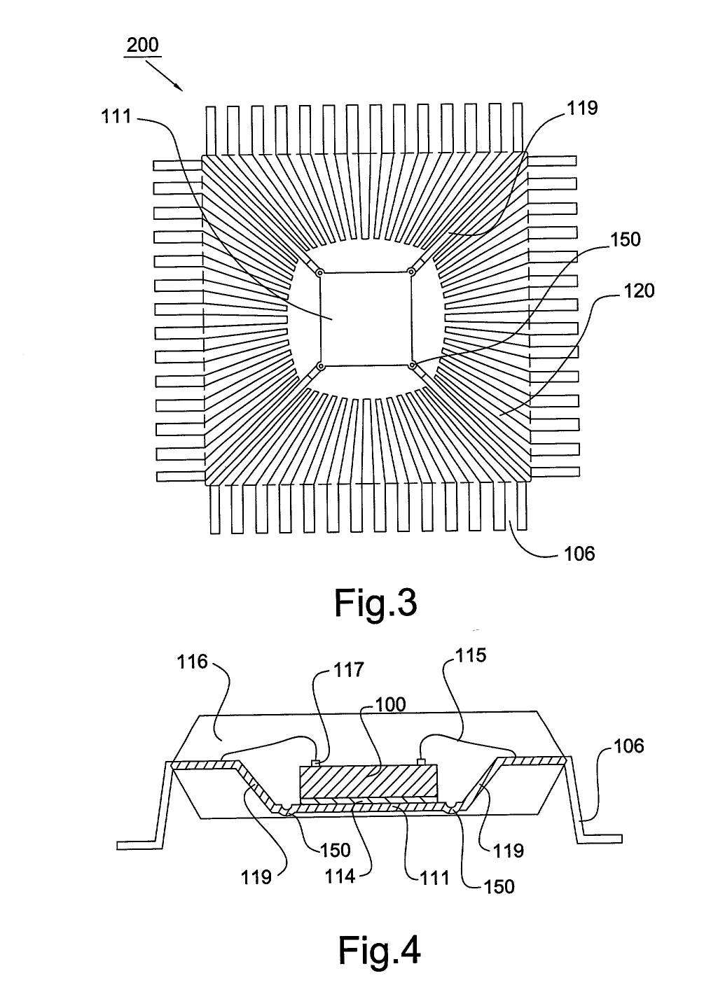

FIG. 3 depicts a lead frame 200 according to the present invention. The lead frame 200 comprises an upper surface and a lower surface, a plurality of leads 120 each having an inner portion defining a central area and a die pad 111 disposed in the central area and connected to the lead frame 200 by a plurality of tie bars 119. The lead frame 200 is provided a plurality of downward protuberances 150 disposed on the four corners of the lower surface of the die pad 111 or on the tie bars 119 adjacent to the four corners of the die pad 111. The downward protuberances 150 can be formed by punching. In the following description, the protuberances 150 disposed on the four corners of the lower surface of the die pad 111 will be described in detail for illustration, and for brevity, the protuberances disposed on the tie bars 119 adjacent to the four corners of the die pad 111 will not be repeatedly described.

Now reffering to FIG. 4, it depicts a sectional view of the chip 100 and the lead frame 200 alone the diagonal of the chip 100 after encapsulating. In the process of encapsulating, the chip 100 is typically attached to the die pad 111 through silver epoxy 114 and the lead frame 200 with the chip 100 is placed in a mold, and then the molding compound such as epoxy will be injected into the cavity of the mold so as to form the package body 116. As described in the foregoing descriptions, because of the weak strength of the tie bars 119 of the lead frame 200 and the position deviation the die pad 111, the elements in the semiconductor chip package after encapsulating would not be in their accurate place respectively. However, in the encapsulating process, the protuberances 150 on the die pad 111 of the lead frame 200 according to the present invention is in contact with the bottom surface of the cavity of the mold to increase the stability of the die pad 111 such that the position of the die pad 111 and the chip 110 will not be disturbed during the molding compound injecting process.

Moreover, in the encapsulating process, the die pad 111 can be forced by the tie bars 119 such that the protuberances 150 of the die pad 111 is more securely disposed against the bottom surface of the cavity. During the molding compound 116 injecting, the flow of the molding compound 116 will not influence the position of the die pad 111 and the phenomenon of paddle shift can be reduced. Therefore, the die pad 111 can be positioned securely in place.

Besides, since the protuberances 150 of the die pad 111 is securely disposed against the bottom surface of the cavity, the downset amount of the die pad 111 can be increased, and the portion of the package body 116 above the upper surface of the die pad 111 is also increased, thereby preventing the bonding wires 115 and the die pad 111 from exposed outside the package body 116.

As described in the foregoing descriptions, the die pad 111 according to the present invention provides the four protuberances 150. But in fact, only one protuberance is required to be in contact with the bottom surface of the cavity for positioning the die pad 111, and the lead frame 200 and the chip 100 thereon in the semiconductor chip package can be positioned in place. Also, only three coplaner protuberances are required to be in contact with the bottom surface of the cavity, and the die pad 111 can be positioned securely in parallel with the bottom surface of the cavity to prevent the die pad 111 from shifting.

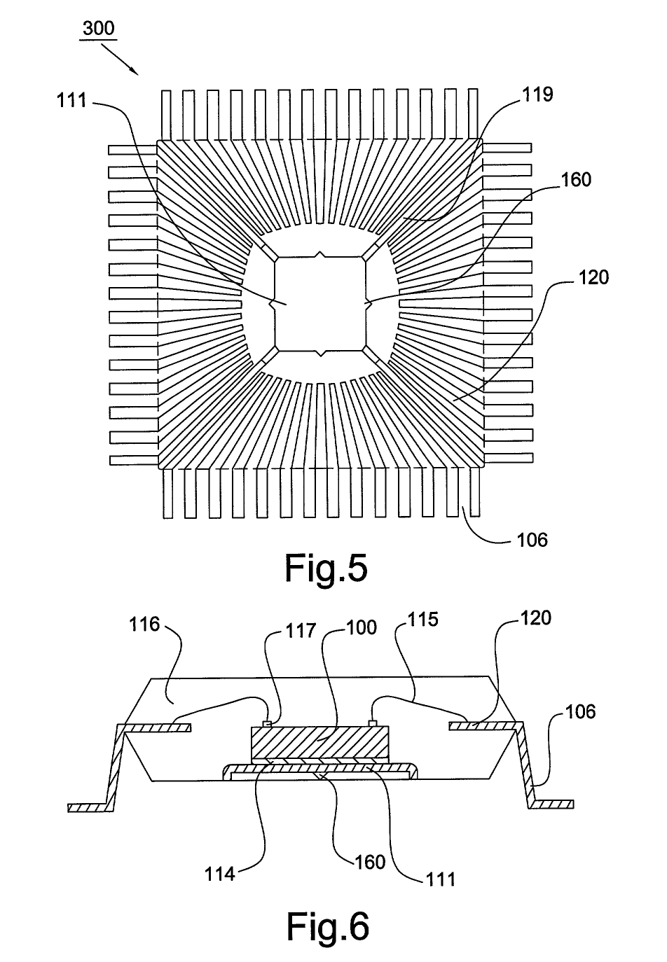

Now referring to FIGS. 5 and 6, they depict a lead frame 300 according to another embodiment of the present invention, and a sectional view of the chip 100 and the lead frame 300 after encapsulated alone the central line of the chip 100. The edges of a die pad 111 of the lead frame 300 are provided a plurality of fins 160. The fins 160 in the shape of downward extension (as shown in FIG. 6) can be formed by punching and bending. Thus, the fins 160 function as the protuberances 150 of the lead frame 200 to allow the die pad 111 to be positioned securely in place.

As described in the foregoing descriptions, the lead frame structure according to the present invention provides a downward extension element, such as protuberances 150 or fins 160. The downset of the die pad of the lead frame can be deeper than that of the conventional die pad. When the lead frame is placed in the mold in the molding pocess of the package body, the plurality of tie bars will force the die pad against the bottom surface of the cavity of the mold to securely dispose the die pad in the mold such that the die pad will not be shifted by the drag force of the molding compound.

The chip package structure according to the present invention can position the lead frame and the chip thereon by the protuberances of the die pad. Therefore, the semiconductor chip package formed by the lead frame of the present invention can position the chip, the bonding wires and the lead frame in place and prevent the bonding wires and the die pad from being exposed outside the package body, so as to assure the quality of the semiconductor chip package.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductor chip package comprising:
a lead frame having a plurality of leads and a die pad, the inner portions of the leads defining a center area and the die pad being disposed in the center area and having at least one downward protuberance on the edge of the die pad;
a semiconductor chip attached on the die pad and having a plurality of bonding pads on the active surface thereof;
a plurality of bonding wires connecting the inner portions of the plurality of leads and the plurality of bonding pads of the semiconductor chip; and
a package body encapsulating the lead frame, the semiconductor chip and the plurality of bonding wires, wherein the at least one protuberance of the die pad of the lead frame is exposed outside the package body.

2. The semiconductor chip package of claim 1, wherein a portion of lead is exposed outside the package body.

3. The semiconductor chip package of claim 1, wherein the lead frame comprises a plurality of tie bars for connecting the die pad and the die pad is downset below the inner portions of the leads.

4. The semiconductor chip package of claim 3, wherein the protuberance of the die pad is disposed against the bottom surface of a mold cavity in the encapsulating process of the semiconductor chip package so as to increase the stability of the the die pad.

5. The semiconductor chip package of claim 1, wherein the die pad of the lead frame comprises at least three coplanner protuberances, and the three coplanner protuberances are exposed outside the package body.

6. A lead frame structure for a semiconductor chip package comprising:
a plurality of leads having inner portions defining a center area;
a die pad located in the center area of the plurality of leads; and
a plurality of tie bars connecting the die pad and the lead frame;
wherein the die pad is downset below the inner portions of the plurality of leads and is provided with at least one downward protuberance.

7. The leads frame structure of claim 6, wherein the lead frame comprises four tie bars for connenting the die pad.

8. The leads frame structure of claim 6, wherein the die pad is provided with at least three coplaner protuberances.

9. The leads frame structure of claim 6, wherein at least one protuberance is located on the corner of the die pad.

10. The leads frame structure of claim 6, wherein at least one protuberance is located on the edge of the die pad.

11. A lead frame structure for a semiconductor chip package comprising:
a plurality of leads having inner portions defining a center area;
a die pad located in the center area of the plurality of leads; and
a plurality of tie bars connecting the die pad and the lead frame;
wherein the die pad is downset below the inner portions of the plurality of leads and is provided with a plurality of downward protuberances located on the tie bars adjacent to the corners of the die pad.

12. The leads frame structure of claim 11, wherein the lead frame comprises four tie bars for connenting the die pad.

13. The leads frame structure of claim 11, wherein the plurality of the protuberances are coplaner.

14. A lead frame structure for a semiconductor chip package comprising:
a plurality of leads having inner portions defining a center area;
a die pad located in the center area of the plurality of leads; and
a plurality of tie bars connecting the die pad and the lead frame;
wherein the die pad is downset below the inner portion of the plurality of leads and is provided with a plurality of downward fins located on the edges of the die pad.

15. The leads frame structure of claim 14, wherein the lead frame comprises four tie bars for connenting the die pad.

16. The leads frame structure of claim 14, wherein the plurality of the downward fins are located on the four edge of the die pad.
